(19) United States
(12) Patent Application Publication
(10) Pub. No.: US 2025/0374584 A1
(43) Pub. Date: Dec. 4, 2025

(54) SOURCE/DRAIN BOTTOM ISOLATION LAYER WITH VOIDS FOR SEMICONDUCTOR DEVICES

(71) Applicant: Taiwan Semiconductor Manufacturing Company, Ltd., Hsinchu (TW)

(72) Inventors: Chun Yi CHOU, Hsinchu City (TW); Guan-Lin CHEN, Hsinchu County (TW); Kuo-Cheng CHIANG, Hsinchu County (TW); Chih-Hao WANG, Hsinchu (TW)

(73) Assignee: Taiwan Semiconductor Manufacturing Company, Ltd., Hsinchu (TW)

(21) Appl. No.: 18/935,199

(22) Filed: Nov. 1, 2024

Related U.S. Application Data
(60) Provisional application No. 63/655,433, filed on Jun. 3, 2024.

(51) Int. Cl. H01L 29/775; H01L 29/06; H01L 29/08; H01L 29/423; H01L 29/66; H01L 29/786

(52) U.S. Cl. CPC H10D 30/43; H10D 30/014; H10D 30/6735; H10D 30/6757; H10D 62/121; H10D 62/151; H10D 64/017

(57) ABSTRACT

The present disclosure describes a semiconductor device having a source/drain (S/D) bottom isolation layer with voids. The semiconductor device includes a stack of semiconductor layers on a substrate, a gate structure surrounding the stack of semiconductor layers, a S/D structure on the substrate and adjacent to the gate structure, and an isolation layer between the S/D structure and the substrate. The isolation layer encloses a void below the S/D structure.

### CROSS-REFERENCE TO RELATED APPLICATION

This application claims the benefit of U.S. Provisional Patent Application No. 63/655,433, titled “Source/Drain Bottom Isolation and Tunnel Scheme for Semiconductor Devices,” filed Jun. 3, 2024, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs)), gate-all-around field effect transistors (GAAFETs), complementary field effect transistors (CFETs), nanosheet transistors, nanowire transistors, multi-bridge channel transistors, nano-ribbon transistors, and other similar structured transistors. Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a source/drain bottom isolation layer with voids, in accordance with some embodiments.

FIGS. 2-4 illustrate partial cross-sectional views of a semiconductor device having a source/drain bottom isolation layer with voids, in accordance with some embodiments.

FIG. 5 is a flow diagram of a method for fabricating a semiconductor device having a source/drain bottom isolation layer with voids, in accordance with some embodiments.

FIGS. 6-21 illustrate partial isometric views of a semiconductor device having a source/drain bottom isolation layer with voids at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, a nanostructure transistor on a substrate can have a gate structure wrapped around a channel structure to improve device performance. The nanostructure transistor can have inner spacers to isolate the gate structure from source/drain (S/D) structures. A leakage current can flow between the S/D structures through the substrate below the channel structure. An isolation layer can be disposed between the S/D structures and the substrate to reduce the leakage current. However, S/D structures grown on the isolation layer can have dislocation defects and thus can reduce device performance of the nanostructure transistor.

Various embodiments in the present disclosure provide methods for forming a S/D bottom isolation layer with voids in a semiconductor device (e.g., a nanostructure transistor) and/or other semiconductor devices in an integrated circuit (IC). In some embodiments, a semiconductor device can include a stack of semiconductor layers on a substrate. A gate structure can wrap around the stack of semiconductor layers. A S/D structure can be disposed on the substrate and in contact with the stack of semiconductor layers. An isolation layer can be disposed between the S/D structure and the substrate. The isolation layer can enclose a void below the S/D structure and the substrate. In some embodiments, the isolation layer can extend below the stack of semiconductor layers. In some embodiments, the semiconductor device can optionally include a dummy semiconductor layer between the gate structure and the isolation layer. With the isolation layer having the void between the S/D structure and the substrate, the leakage current path from the S/D structure to the substrate can be blocked and the dislocation defects in the S/D structure can be reduced. Accordingly, the isolation layer with the void can reduce the leakage current and improve the device performance.

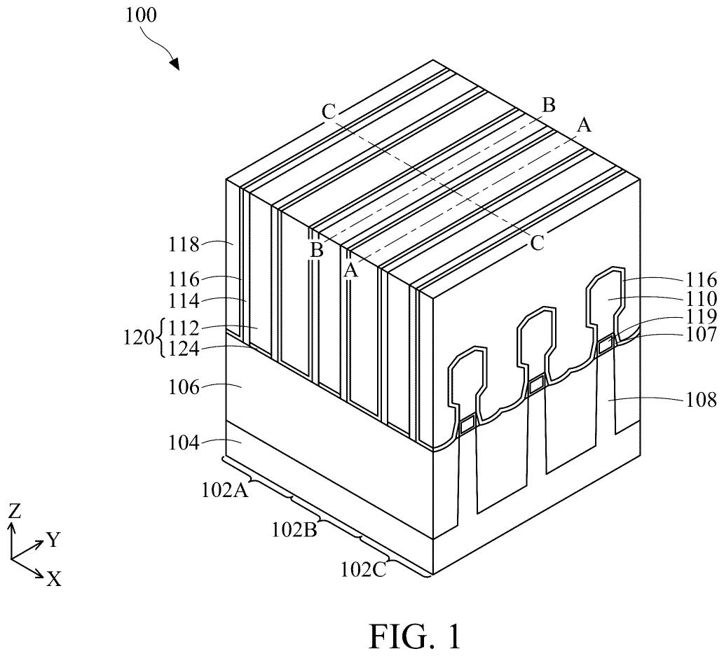

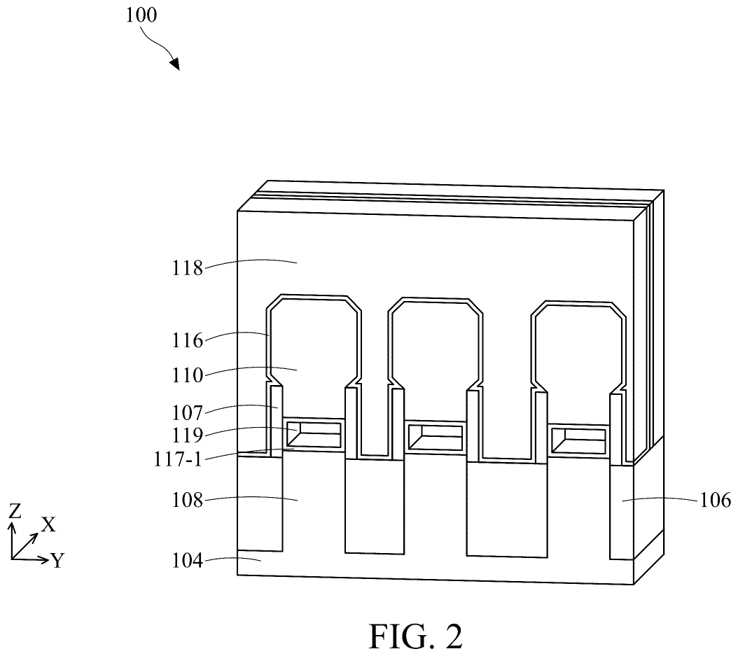

FIG. 1 illustrates an isometric view of a semiconductor device 100 having a S/D bottom isolation layer with voids, in accordance with some embodiments. FIGS. 2-4 illustrate partial cross-sectional views of semiconductor device 100 across lines A-A, B-B, and C-C shown in FIG. 1, respectively, in accordance with some embodiments. In some embodiments, semiconductor device 100 can include transistors 102A-102C, as shown in FIG. 1. In some embodiments, transistors 102A-102C can include nanostructure transistors. The nanostructure transistors can include FinFETs, gate-all-around field effect transistors (GAA FETs), nanosheet transistors, nanowire transistors, multi-bridge channel transistors, nano-ribbon transistors, and other similar structured transistors. The nanostructure transistors can provide a channel in a stacked nanosheet/nanowire configuration.

In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-4, semiconductor device 100 having transistors 102A-102C can be formed on a substrate 104 and can be isolated by shallow trench isolation (STI) regions 106. Each of transistors 102A-102C can include fin structures 108, bottom isolation layer 117, dummy semiconductor layer 115, nanostructures 122-1, 122-2, and 122-3 (collectively referred to as “nanostructures 122”), sidewall spacers 107, gate structures 120, gate spacers 114, inner spacers 121, S/D structures 110, etch stop layer (ESL) 116, and interlayer dielectric (ILD) layer 118.

Referring to FIGS. 1-4, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-4, nanostructures 122, dummy semiconductor layer 115, and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1-4, nanostructures 122, dummy semiconductor layer 115, and fin structures 108 can extend along an X-axis for transistors 102A-102C. In some embodiments, nanostructures 122, dummy semiconductor layer 115, and fin structures 108 can be disposed on substrate 104. Nanostructures 122 can include a set of nanostructures 122-1, 122-2, and 122-3, which can be in the form of semiconductor layers, nanosheets, nanowires, or nano-ribbons. Each of nanostructures 122 can act as a channel structure and can form a channel region underlying gate structures 120 of transistors 102A-102C. In some embodiments, dummy semiconductor layer 115 can be optional. In some embodiments, dummy semiconductor layer 115 can be partially or completely removed during the formation of bottom isolation layer 117. In some embodiments, dummy semiconductor layer 115 can be in the form of nanosheets, nanowires, or nanoribbons.

In some embodiments, nanostructures 122, dummy semiconductor layer 115, and fin structures 108 can include semiconductor materials similar to or different from substrate 104. In some embodiments, nanostructures 122, dummy semiconductor layer 115, and fin structures 108 can include silicon. The semiconductor materials of nanostructures 122, dummy semiconductor layer 115, and fin structures 108 can be undoped or can be in-situ doped during their formation process. In some embodiments, as shown in FIG. 2-4, nanostructures 122 under gate structures 120 can form channel regions of semiconductor device 100 and represent current carrying channel structures of semiconductor device 100. In some embodiments, nanostructures 122 can have a thickness 122t ranging from about 3 nm to about 15 nm. Though three layers of nanostructures 122 are shown in FIGS. 2-4, transistors 102A-102C can have any number of nanostructures 122.

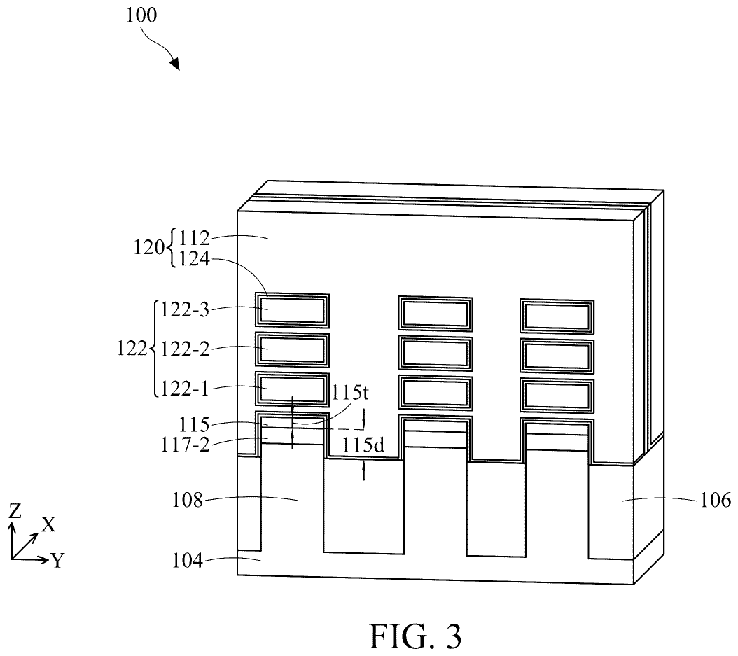

In some embodiments, dummy semiconductor layer 115 can be disposed between gate structures 120 and bottom isolation layer 117. In some embodiments, dummy semiconductor layer 115 can have a thickness 115t ranging from about 0 nm to about 10 nm. In some embodiments, dummy semiconductor layer 115 can be partially or completely removed during the formation process of bottom isolation layer 117 and dummy semiconductor layer 115 can be optional in semiconductor device 100. In some embodiments, a ratio of thickness 115t to thickness 122t can range from about 0 to about 0.7. If dummy semiconductor layer 115 is completely removed during the formation process of bottom isolation layer 117, thickness 115t can be about 0 nm and the ratio can be about 0. If thickness 115t is greater than about 10 nm or the ratio is greater than about 0.7, bottom isolation layer 117 may not be formed below S/D structures 110 or nanostructures 122. In some embodiments, as shown in FIG. 3, a distance 115d between top surfaces of STI regions 106 and a bottom surface of dummy semiconductor layer 115 can range from about 5 nm to about 20 nm. In some embodiments, a ratio of distance 115d to thickness 122t can range from about 1 to about 1.5. If distance 115d is less than about 5 nm or the ratio is less than about 1, bottom isolation layer 117 may not be formed with void 119 under S/D structures 110. If distance 115d is greater than about 20 nm or the ratio is greater than about 1.5, bottom isolation layer 117 may not enclose void 119 and the leakage current may increase.

Referring to FIGS. 1-4, gate structures 120 can include gate dielectric layer 124 and gate electrode 112. In some embodiments, gate dielectric layer 124 can be formed on nanostructures 122, dummy semiconductor layer 115, fin structures 108, and STI regions 106. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

In some embodiments, as shown in FIGS. 1-4, gate electrode 112 can be disposed on gate dielectric layer 124. In some embodiments, gate electrode 112 can include one or more work function metal layers and a metal fill. The one or more work function metal layers can include work function metals to tune the threshold voltage (Vt) of transistors 102A-102C. In some embodiments, gate electrode 112 for NFET and PFET devices can have the same work-function metal. In some embodiments, gate electrode 112 for NFET and PFET devices can have different work-function metals. In some embodiments, as shown in FIG. 2-4, each of nanostructures 122 can be wrapped around by gate structures 120, for which gate structures 120 can be referred to as “gate-all-around (GAA) structures” and transistors 102A-102C can also be referred to as “GAA FETs 102A-102C.” The one or more work function metal layers can wrap around nanostructures 122 and can include work function metals to tune the Vt of transistors 102A-102C. In some embodiments, transistors 102A-102C can include any number of work function metal layers for Vt tuning (e.g., ultra-low Vt, low Vt, and standard Vt).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1-4, gate spacers 114 can be disposed on sidewalls of gate structures 120, sidewall spacers 107 can be disposed on sidewalls of fin structures 108, and inner spacers 121 can be disposed between gate structures 120 and S/D structures 110. Gate spacers 114, sidewall spacers 107, and inner spacers 121 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114, sidewall spacers 107, and inner spacers 121 can include a same insulating material. In some embodiments, gate spacers 114, sidewall spacers 107, and inner spacers 121 can include different insulating materials. Gate spacers 114, sidewall spacers 107, and inner spacers 121 can include a single layer or a stack of insulating layers. Gate spacers 114, sidewall spacers 107, and inner spacers 121 can have a low-k material with a dielectric constant less than about 3.9 (e.g., about 3.5, about 3.0, or about 2.8).

S/D structures 110 can be disposed on fin structures 108 and in contact with nanostructures 122. In some embodiments, S/D structures 110 can be disposed between adjacent stacks of nanostructures 122 and on opposing sides of gate structures 120. S/D structures 110 can function as S/D regions of transistors 102A-102C. In some embodiments, S/D structures 110 can have any geometric shape, such as a polygon, an ellipse, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structures 120. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

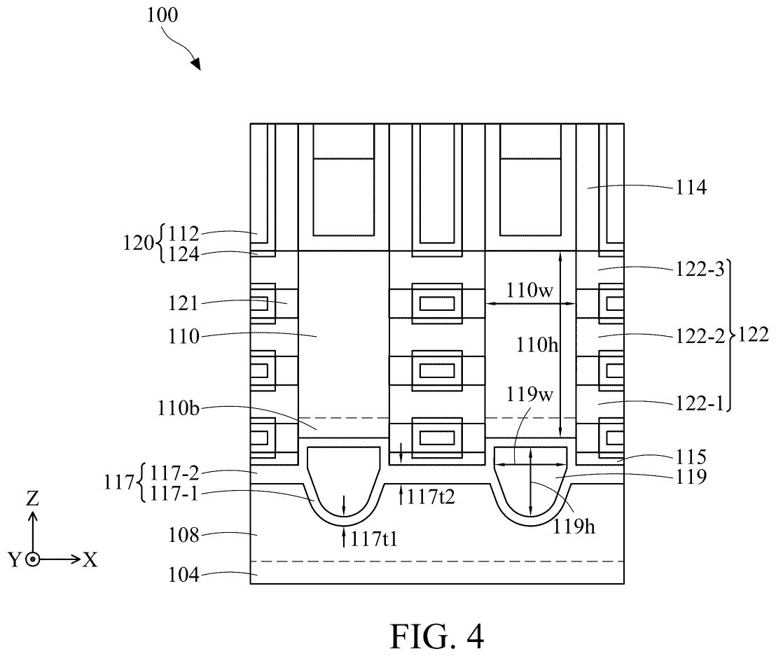

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions. In some embodiments, as shown in FIG. 4, S/D structures 110 can have a width 110w along an X-axis ranging from about 20 nm to about 40 nm. In some embodiments, S/D structures 110 can have a height 110h along a Z-axis ranging from about 50 nm to about 100 nm. In some embodiments, as shown in FIG. 4, S/D structures 110 can include silicon germanium. A portion 110b of S/D structures 110 in contact with bottom isolation layer 117 can include boron doped silicon. The boron doped silicon in portion 110b can act as an etch stop layer and can protect S/D structures 110 during the formation of bottom isolation layer 117. In some embodiments, portion 110b of S/D structures 110 can have a thickness ranging from about 3 nm to about 5 nm to protect S/D structures 110.

In some embodiments, as shown in FIGS. 2-4, bottom isolation layer 117 can include a first portion 117-1 disposed below S/D structures 110 and a second portion 117-2 disposed below nanostructures 122. In some embodiments, bottom isolation layer 117 can include silicon oxide, silicon nitride, silicon oxynitride, silicon carbonitride, silicon oxycarbide, silicon oxycarbonitride, hafnium oxide, aluminum oxide, or other suitable dielectric materials. In some embodiments, bottom isolation layer 117 can be a bi-layer or multi-layer structure. In some embodiments, first portion 117-1 of bottom isolation layer 117 can include a void 119 between S/D structures 110 and fin structures 108. Bottom isolation layer 117 can enclose void 119 under S/D structures 110.

In some embodiments, top surfaces of first portion 117-1 of bottom isolation layer 117 can be below bottom surfaces of bottom nanostructure 122-1 to reduce contact resistance of S/D structures 110 and improve device performance. In some embodiments, dummy semiconductor layer 115 can be disposed between gate structures 120 and bottom isolation layer 117, and the top surfaces of first portion 117-1 of bottom isolation layer 117 can be coplanar with bottom surfaces of bottommost inner spacers 121 to further reduce contact resistance and improve device performance. In some embodiments, gate structures 120 can be disposed on bottom isolation layer 117 with no dummy semiconductor layer 115, and the top surfaces of first portion 117-1 of bottom isolation layer 117 can be coplanar with bottom surfaces of bottommost inner spacers 121 to further reduce contact resistance and improve device performance. In some embodiments, the top surfaces of first portion 117-1 of bottom isolation layer 117 can be above top surfaces of dummy semiconductor layer 115 to ensure the formation of bottom isolation layer 117 with void 119 under S/D structures 110. In some embodiments, the top surfaces of first portion 117-1 of bottom isolation layer 117 can be coplanar with bottom surfaces of bottommost inner spacers 121 and dummy semiconductor layer 115 can be removed. If the top surfaces of first portion 117-1 or bottom surfaces of S/D structures 110 is below top surfaces of dummy semiconductor layer 115, the dielectric materials of bottom isolation layer 117 may not be deposited in void 119 and first portion 117-1 of bottom isolation layer 117 may not be formed under S/D structures 110. Additionally, dummy semiconductor layer 115 may be in contact with S/D structures 110 and the leakage current of semiconductor device 100 may increase.

In some embodiments, as shown in FIG. 4, first portion 117-1 of bottom isolation layer 117 enclosing void 119 below S/D structures 110 can have a thickness 117t1 ranging from about 0.5 nm to about 4 nm. In some embodiments, second portion 117-2 of bottom isolation layer 117 below nanostructures 122 can have a thickness 117t2 along a Z-axis ranging from about 1 nm to about 10 nm. In some embodiments, second portion 117-2 can have a width along a Y-axis ranging from about 5 nm to about 80 nm. In some embodiments, second portion 117-2 can have a length along an X-axis ranging from about 10 nm to about 100 nm. In some embodiments, a first ratio of thickness 117t1 to thickness 122t can range from about 0.1 to about 0.3. A second ratio of thickness 117t2 to thickness 122t can range from about 0.2 to about 0.8. In some embodiments, if thickness 117t1 is less than about 0.5 nm or the first ratio is less than about 0.1, bottom isolation layer 117 may not isolate S/D structures 110 from fin structures 108 and the leakage current may increase. If thickness 117t1 is greater than about 4 nm or the first ratio is greater than about 0.3, the dimension of void 119 may be reduced and the parasitic capacitance of S/D structures 110 may be increased. In some embodiments, if thickness 117t2 is less than about 1 nm or the second ratio is less than about 0.2, bottom isolation layer 117 with void 119 may not be formed. If thickness 117t2 is greater than about 10 nm or the second ratio is greater than about 0.8, manufacturing cost may increase and the dimension of void 119 may be reduced.

In some embodiments, as shown in FIG. 4, void 119 can have a height 119h along a Z-axis ranging from about 5 nm to about 25 nm. In some embodiments, void 119 can have a width 119w along an X-axis ranging from about 15 nm to about 40 nm. In some embodiments, a third ratio of height 119h to height 110h can range from about 0.1 to about 0.4. A fourth ratio of width 119w to width 110w can range from about 0.7 to about 1.0. If height 119h is less than about 5 nm, the third ratio is less than about 0.1, width 119w is less than about 15 nm, or the fourth ratio is less than about 0.7, the leakage current in S/D structures 110 may increase. If height 119h is greater than about 25 nm, the third ratio is greater than about 0.4, width 119w is greater than about 40 nm, or the fourth ratio is greater than about 1.0, the dimension of S/D structures 110 may decrease and the device current may decrease.

Referring to FIGS. 1-4, ESL 116 can be disposed on STI regions 106, S/D structures 110, and sidewalls of gate spacers 114 and sidewall spacers 107. ESL 116 can be configured to protect STI regions 106, S/D structures 110, and gate structures 120 during the formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

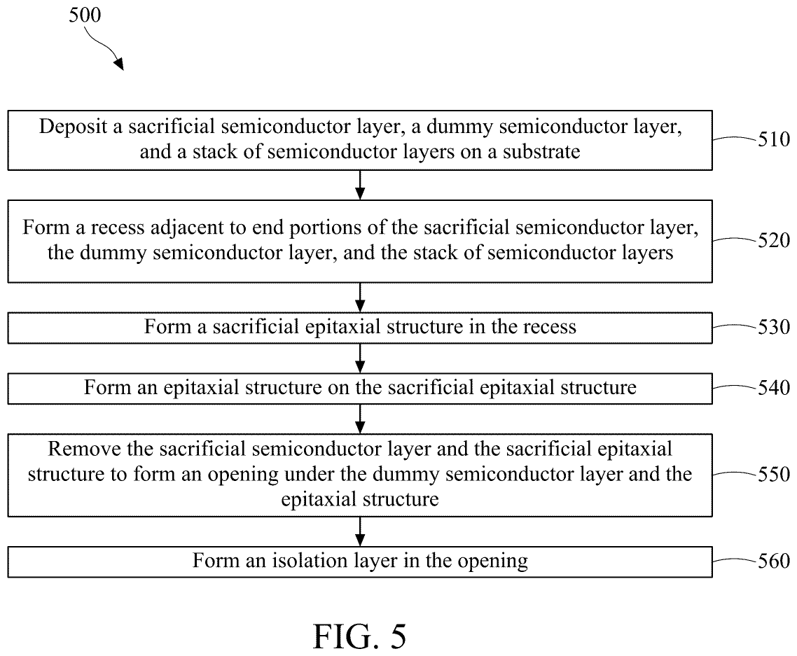

FIG. 5 is a flow diagram of a method 500 for fabricating semiconductor device 100 having a S/D bottom isolation layer with voids, in accordance with some embodiments. Method 500 may not be limited to nanostructure transistor devices and can be applicable to other devices that would benefit from the S/D structure with a void. Additional fabrication operations may be performed between various operations of method 500 and may be omitted merely for clarity and ease of description. Additional processes can be provided before, during, and/or after method 500; one or more of these additional processes are briefly described herein. Moreover, not all operations may be needed to perform the disclosure provided herein. Additionally, some of the operations may be performed simultaneously or in a different order than shown in FIG. 5. In some embodiments, one or more other operations may be performed in addition to or in place of the presently-described operations.

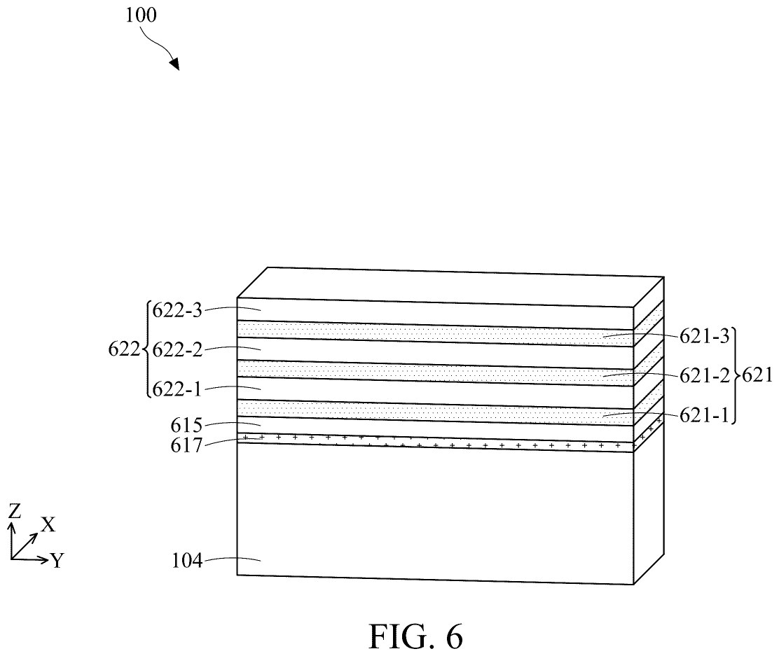

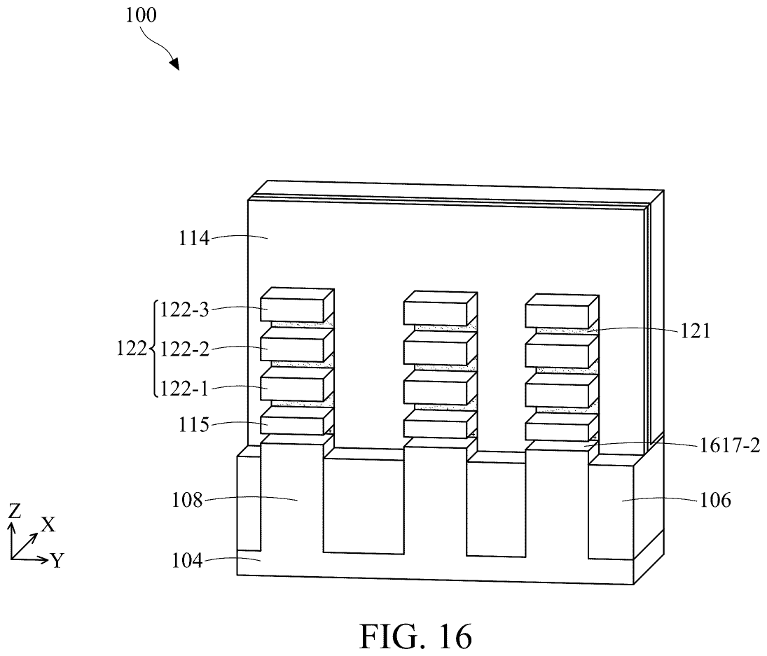

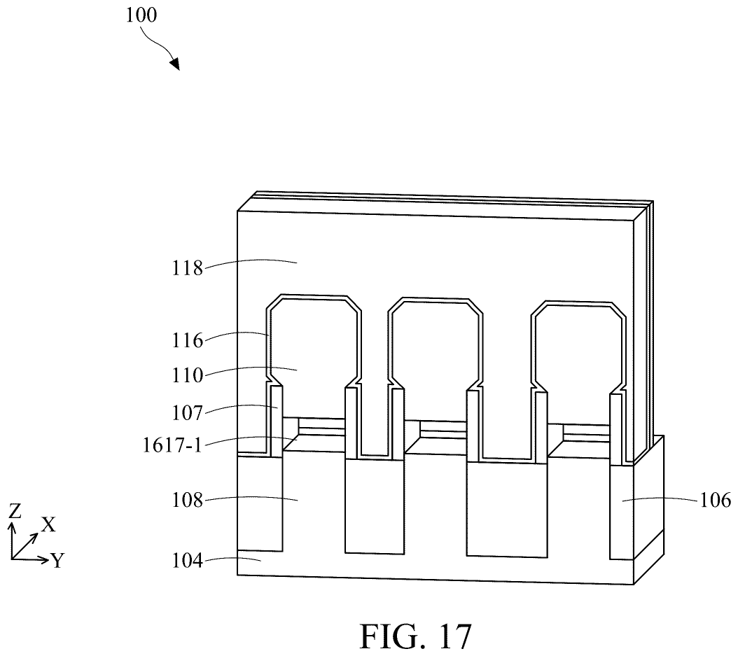

For illustrative purposes, the operations illustrated in FIG. 5 will be described with reference to the example fabrication process for fabricating semiconductor device 100 as illustrated in FIGS. 6-21. FIGS. 6-21 illustrate partial isometric views of semiconductor device 100 having a S/D bottom isolation layer with voids at various stages of its fabrication, in accordance with some embodiments. In some embodiments, Elements in FIGS. 6-21 with the same annotations as elements in FIGS. 1-4 are described above.

In referring to FIG. 5, method 500 begins with operation 510 and the process of depositing a sacrificial semiconductor layer, a dummy semiconductor layer, and a stack of semiconductor layers on a substrate. For example, as shown in FIG. 6, sacrificial semiconductor layer 617, dummy semiconductor layer 615, and a stack of semiconductor layers 621-1, 621-2, and 621-3 (collectively referred to as “semiconductor layers 621”) and semiconductor layers 622-1, 622-2, and 622-3 (collectively referred to as “semiconductor layers 622”) can be deposited on substrate 104. In some embodiments, as shown in FIG. 6, semiconductor layers 621 and 622 can be stacked in an alternate configuration. In some embodiments, sacrificial semiconductor layer 617, dummy semiconductor layer 615, and the stack of semiconductor layers 621 and 622 can be epitaxially grown on substrate 104.

In some embodiments, sacrificial semiconductor layer 617, dummy semiconductor layer 615, and the stack of semiconductor layers 621 and 622 can include semiconductor materials similar to or different from substrate 104. In some embodiments, semiconductor layers 621 and 622 can include different semiconductor materials. In some embodiments, sacrificial semiconductor layer 617 can include silicon germanium with a germanium concentration ranging from about 30% to about 60%. In some embodiments, dummy semiconductor layer 615 can include silicon. In some embodiments, semiconductor layers 621 can include silicon germanium with a germanium concentration ranging from about 20% to about 30%. In some embodiments, semiconductor layers 622 can include silicon. In some embodiments, the germanium concentration in sacrificial semiconductor layer 617 can be greater than the germanium concentration in semiconductor layers 621 to ensure complete removal of sacrificial semiconductor layer 617 in subsequent processes.

In some embodiments, sacrificial semiconductor layer 617 can have a thickness along a Z-axis ranging from about 1 nm to about 4 nm. In some embodiments, dummy semiconductor layer 615 can have a thickness along a Z-axis ranging from about 2 nm to about 4 nm. In some embodiments, each of semiconductor layers 621 can have a thickness along a Z-axis ranging from about 3 nm to about 7 nm. In some embodiments, each of semiconductor layers 622 can have a thickness along a Z-axis ranging from about 3 nm to about 15 nm. In some embodiments, the thickness of sacrificial semiconductor layer 617 can be less than the thickness of semiconductor layers 621 to ensure subsequent formation of bottom isolation layer 117.

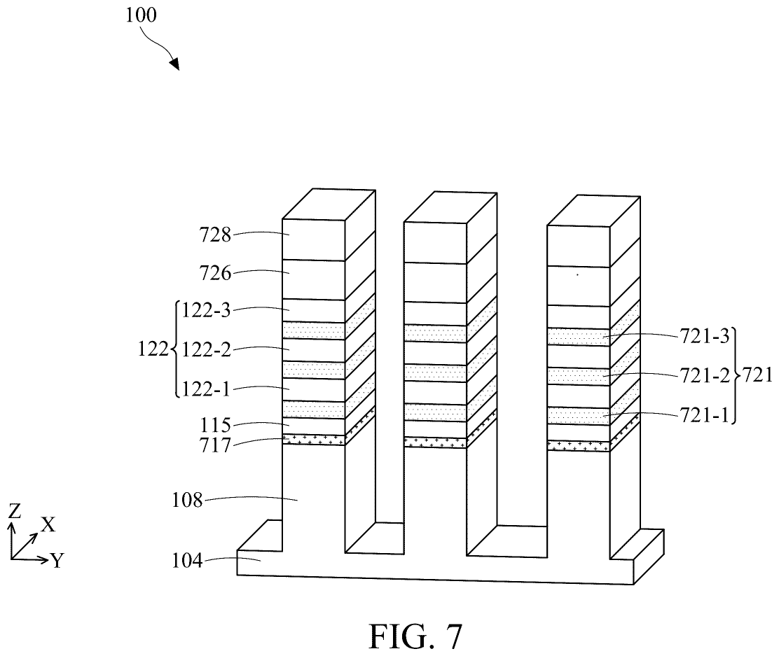

The deposition of sacrificial semiconductor layer 617, dummy semiconductor layer 615, and the stack of semiconductor layers 621 and 622 can be followed by a patterning process to form nanostructures 721 and 122. For example, as shown in FIG. 7, hard mask layers 726 and 728 can be formed on the stack of semiconductor layers 621 and 622 and subsequently patterned to form fin structures 108, sacrificial semiconductor layer 717, dummy semiconductor layer 115, nanostructures 122, and nanostructures 721-1, 721-2, and 721-3 (collectively referred to as “nanostructures 721”). In some embodiments, sacrificial semiconductor layer 717, dummy semiconductor layer 115, and nanostructures 122 and 721 can be in the form of semiconductor layers, nanosheets, nanowires, or nano-ribbons. In some embodiments, fin structures 108 can include the same semiconductor material as substrate 104.

Embodiments of fin structures 108, sacrificial semiconductor layer 717, dummy semiconductor layer 115, and nanostructures 122 and 721 disclosed herein may be patterned by any suitable method. For example, the fin structures and the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin structures and the nanostructures.

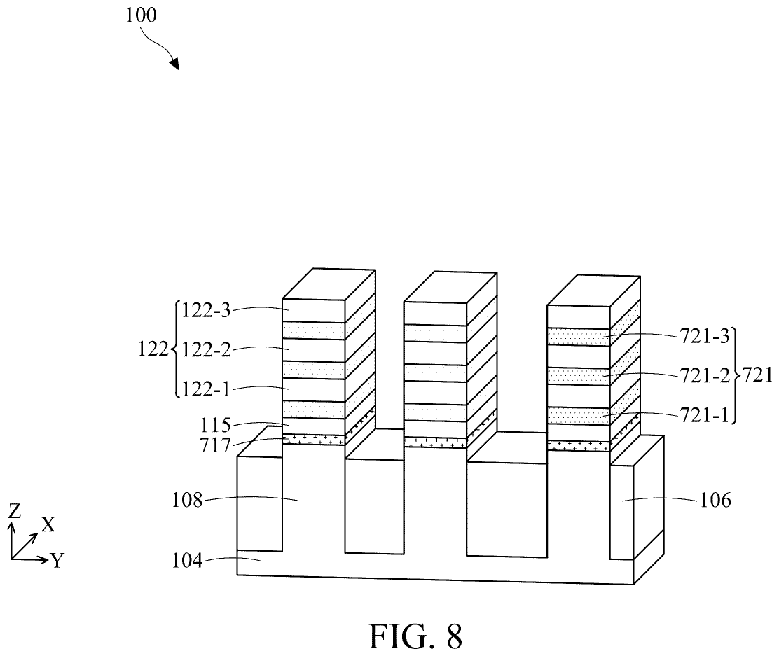

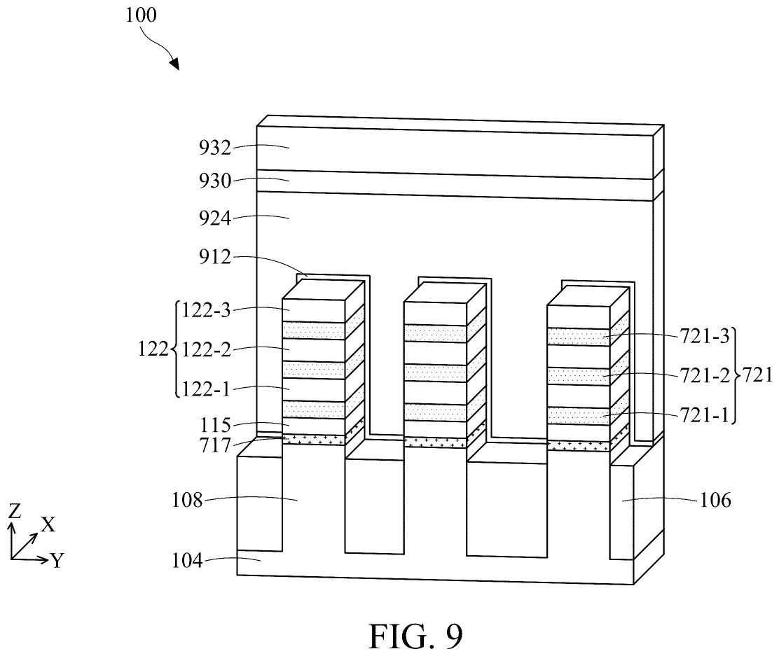

The formation of nanostructures 122 and 721 can be followed by the formation of STI regions 106 between adjacent stacks of nanostructures 122 and 721, as shown in FIG. 8. In some embodiments, STI regions 106 can be recessed such that top surfaces of STI regions 106 can be below sacrificial semiconductor layer 717. The formation of STI regions 106 can be followed by the formation of interfacial layer 912, sacrificial gate structures 924, and hard mask layers 930 and 932 on nanostructures 122 and STI regions 106, as shown in FIG. 9. In some embodiments, sacrificial gate structures 924 can include polysilicon. The formation of sacrificial gate structures 924 can be followed by the formation of gate spacers 114 on sidewalls of sacrificial gate structures 924 and sidewall spacers 107 on sidewalls of sacrificial semiconductor layer 717, dummy semiconductor layer 115, and nanostructures 122 and 721. In some embodiments, gate spacers 114 and sidewall spacers 107 can include insulating materials, such as silicon oxide, silicon nitride, silicon oxynitride, silicon carbonitride, silicon oxycarbide, silicon oxycarbonitride, a low-k material, and a combination thereof.

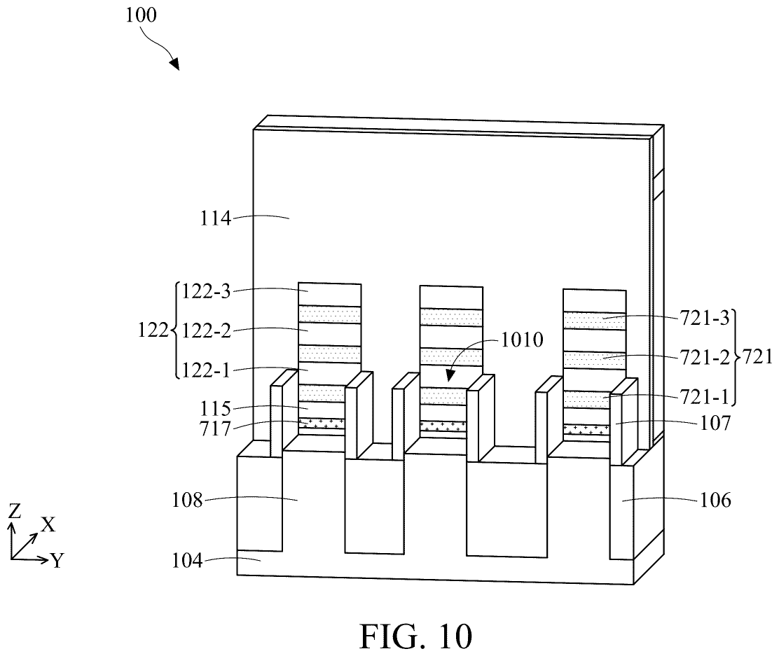

Referring to FIG. 5, in operation 520, a recess can be formed adjacent to end portions of the sacrificial semiconductor layer, the dummy semiconductor layer, and the stack of semiconductor layers. For example, as shown in FIG. 10, recess 1010 can be formed adjacent to end portions of sacrificial semiconductor layer 717, dummy semiconductor layer 115, and nanostructures 122 and 721. In some embodiments, end portions of sacrificial semiconductor layer 717, dummy semiconductor layer 115, and nanostructures 122 and 721 can be vertically etched to form recess 1010. In some embodiments, the vertical recess of sacrificial semiconductor layer 717, dummy semiconductor layer 115, and nanostructures 122 and 721 can expose fin structures 108 to ensure complete removal of sacrificial semiconductor layer 717 on fin structures 108.

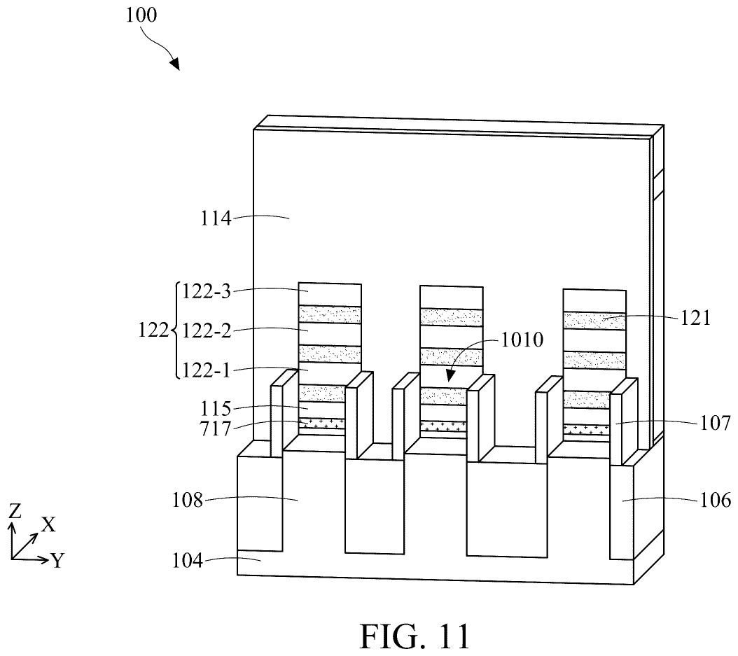

The formation of recess 1010 can be followed by the formation of inner spacers 121, as shown in FIG. 11. In some embodiments, inner spacers 121 can be formed adjacent to end portions of nanostructures 122. In some embodiments, the formation of inner spacers 121 can include a lateral recess of nanostructures 721 and the deposition and trim of a spacer layer. These processes are not described in detail for clarity. In some embodiments, inner spacers 121 can include insulating materials, such as silicon oxide, silicon nitride, silicon oxynitride, silicon carbonitride, silicon oxycarbide, silicon oxycarbonitride, a low-k material, and a combination thereof.

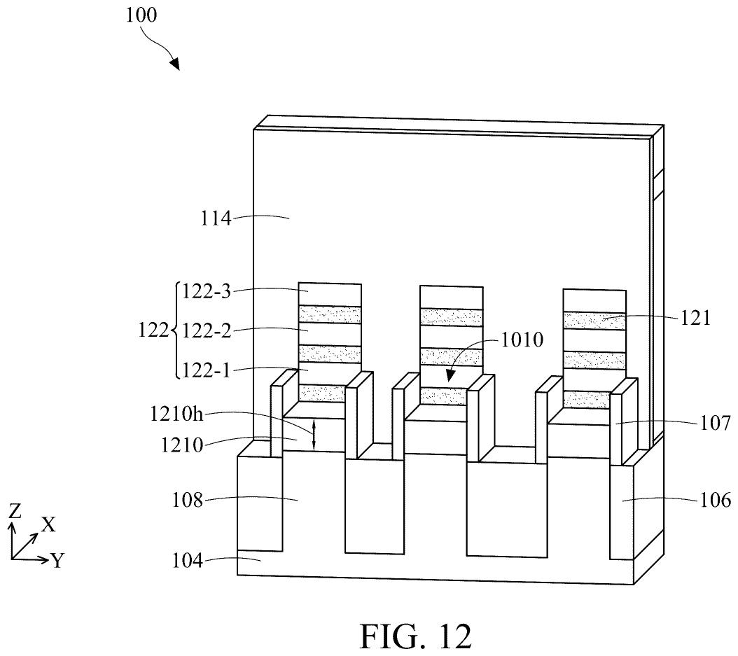

Referring to FIG. 5, in operation 530, a sacrificial epitaxial structure can be formed in the recess. For example, as shown in FIG. 12, sacrificial epitaxial structure 1210 can be formed in recess 1010. In some embodiments, sacrificial epitaxial structure 1210 can be epitaxially grown on fin structures 108 and substrate 104. In some embodiments, sacrificial epitaxial structure 1210 can be epitaxially grown by (i) chemical vapor deposition (CVD), such as low pressure CVD (LPCVD), atomic layer CVD (ALCVD), ultrahigh vacuum CVD (UHVCVD), reduced pressure CVD (RPCVD), and other suitable CVD; (ii) molecular beam epitaxy (MBE) processes; (iii) any suitable epitaxial process; or (iv) a combination thereof. In some embodiments, sacrificial epitaxial structure 1210 can be grown by an epitaxial deposition/partial etch process, which can repeat the epitaxial deposition/partial etch process multiple times. Such repeated deposition/partial etch process can be referred to as a cyclic deposition-etch (CDE) process. The CDE process can reduce epitaxial defects formed during the growth and can control the profiles of sacrificial epitaxial structure 1210.

In some embodiments, sacrificial epitaxial structure 1210 can include an epitaxially-grown semiconductor material different from the material of fin structures 108 and substrate 104, such as silicon germanium. In some embodiments, a germanium concentration in sacrificial epitaxial structure 1210 can range from about 20% to about 50%. In some embodiments, the germanium concentration in sacrificial epitaxial structure 1210 can be greater than the germanium concentration in nanostructures 721 to ensure complete removal of sacrificial epitaxial structure 1210 in subsequent processes. If the germanium concentration is less than about 20%, sacrificial epitaxial structure 1210 may not be completely removed during subsequently processes. If the germanium concentration is greater than about 50%, defects can be formed in sacrificial epitaxial structure 1210 and subsequently-formed S/D structures 110. In some embodiments, sacrificial epitaxial structures 1210 can be undoped. In some embodiments, as shown in FIG. 12, sacrificial epitaxial structure 1210 can have a height 1210h along a Z-axis ranging from about 5 nm to about 25 nm. If 1210h is less than about 5 nm, the leakage current in subsequently-formed S/D structures 110 may increase. If 1210h is greater than about 25 nm, the dimension of subsequently-formed S/D structures 110 may decrease and the device current may decrease. In some embodiments, top surfaces of sacrificial epitaxial structures 1210 can be below bottom surfaces of bottom nanostructure 122-1. In some embodiments, the top surfaces of sacrificial epitaxial structures 1210 can be coplanar with bottom surfaces of bottommost inner spacers 121. In some embodiments, the top surfaces of sacrificial epitaxial structures 1210 can be above top surfaces of dummy semiconductor layer 115.

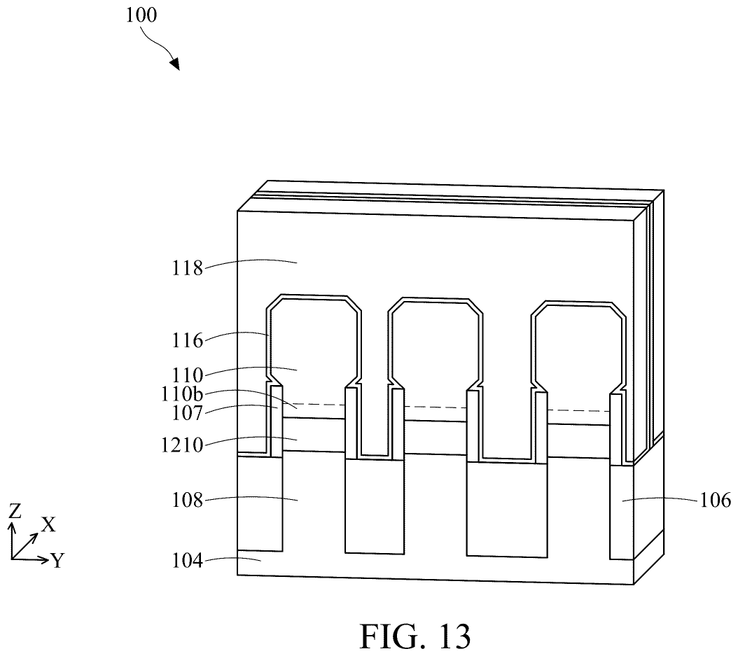

Referring to FIG. 5, in operation 540, an epitaxial structure can be formed on the sacrificial epitaxial structure. For example, as shown in FIG. 13, S/D structures 110 can be formed on sacrificial epitaxial structure 1210. In some embodiments, S/D structures 110 can be epitaxially grown on sacrificial epitaxial structure 1210 and in contact with nanostructures 122. In some embodiments, S/D structures 110 can be epitaxially grown by the same epitaxial process as sacrificial epitaxial structure 1210. In some embodiments, S/D structures 110 grown on sacrificial epitaxial structure 1210 can have minimized dislocation defects and improved device performance. In some embodiments, S/D structures 110 can have any geometric shape, such as a polygon, a cone, a diamond, an ellipse, and a circle. In some embodiments, S/D structures 110 can include an epitaxially-grown semiconductor material, such as silicon (e.g., the same material as substrate 104). In some embodiments, S/D structures 110 can include an epitaxially-grown semiconductor material different from the material of substrate 104, such as silicon germanium, and can impart a strain on the channel regions under gate structures 120.

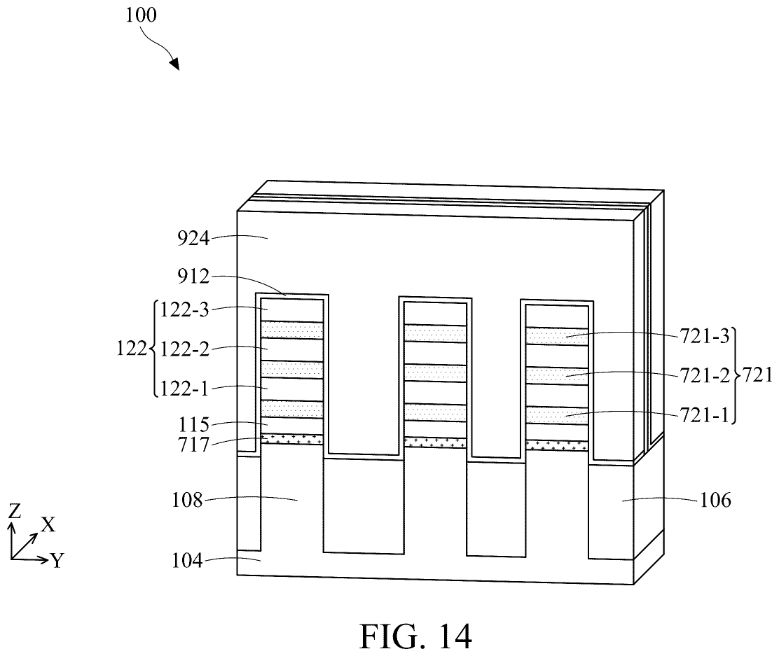

In some embodiments, S/D structures 110 can include silicon and can be in-situ doped during the epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during the epitaxial growth process using p-type dopants, such as boron, indium, and gallium. In some embodiments, S/D structures 110 can include one or more epitaxial layers, where each epitaxial layer can have different compositions and/or different dopant concentrations. In some embodiments, S/D structures 110 can include silicon and the silicon germanium in sacrificial epitaxial structures 1210 can be completely removed in subsequent processes. In some embodiments, as shown in FIG. 13, S/D structures 110 can include silicon germanium. A portion 110b of S/D structures 110 in contact with sacrificial epitaxial structure 1210 can include boron doped silicon. The boron doped silicon in portion 110b can act as an etch stop layer and can protect S/D structures 110 during subsequent removal of sacrificial epitaxial structure 1210. In some embodiments, portion 110b of S/D structures 110 including boron doped silicon can have a thickness ranging from about 3 nm to about 5 nm to protect S/D structures 110. In some embodiments, portion 110b of S/D structures 110 can be epitaxially grown and in-situ doped during the growth of S/D structures 110. The formation of S/D structures can be followed by the formation of ESL 116, the formation of ILD layer 118, and a chemical mechanical polishing (CMP) process to planarize top surfaces of sacrificial gate structures 924, gate spacers 114, and ILD layer 118, as shown in FIGS. 13 and 14.

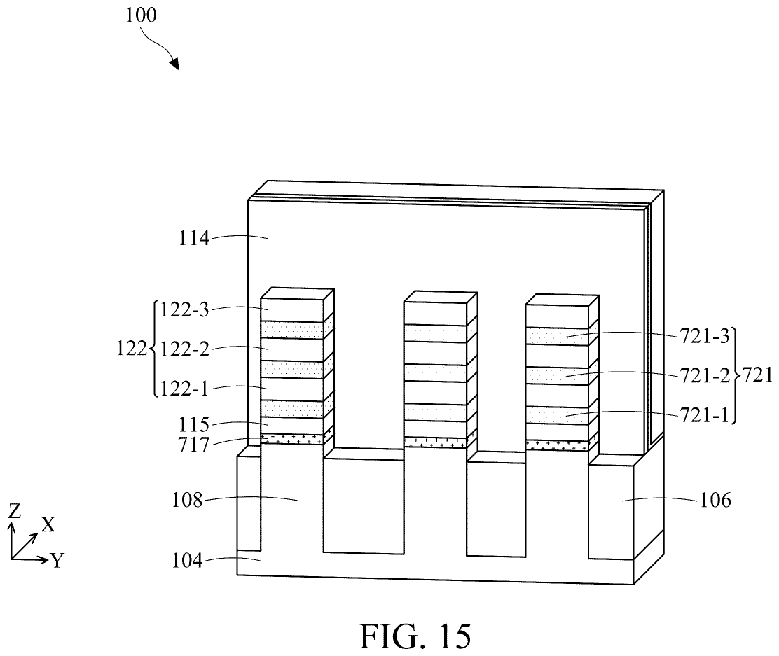

Referring to FIG. 5, in operation 550, the sacrificial semiconductor layer and the sacrificial epitaxial structure are removed to form an opening under the dummy semiconductor layer and the epitaxial structure. For example, as shown in FIGS. 15-17, sacrificial semiconductor layer 717 and sacrificial epitaxial structure 1210 can be removed to form opening 1617. Opening 1617 can include a first portion 1617-1 under S/D structures 110 and a second portion 1617-2 under dummy semiconductor layer 115. In some embodiments, the formation of opening 1617 can include removal of sacrificial gate structures 924 and interfacial layer 912 and removal of nanostructures 721, sacrificial semiconductor layer 717, and sacrificial epitaxial structure 1210.

In some embodiments, nanostructures 721, sacrificial semiconductor layer 717, and sacrificial epitaxial structure 1210 can be removed in a same etching process. The remaining nanostructures 112 can form channel regions of semiconductor device 100. In some embodiments, the etching process can remove sacrificial epitaxial structure 1210 through second portion 1617-2 of opening 1617 after removing sacrificial semiconductor layer 717. In some embodiments, the etching process can include a wet etching process performed at a temperature from about 10° C. to about 70° C. In some embodiments, the wet etching process can include etchants such as oxidants and fluorine ions. In some embodiments, an etching time of the wet etching process can range from about 10 s to about 600 s.

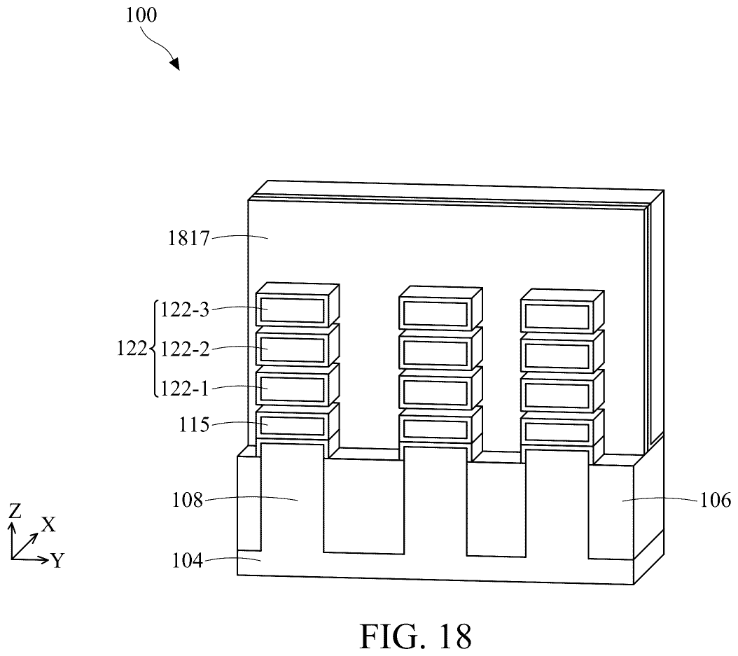

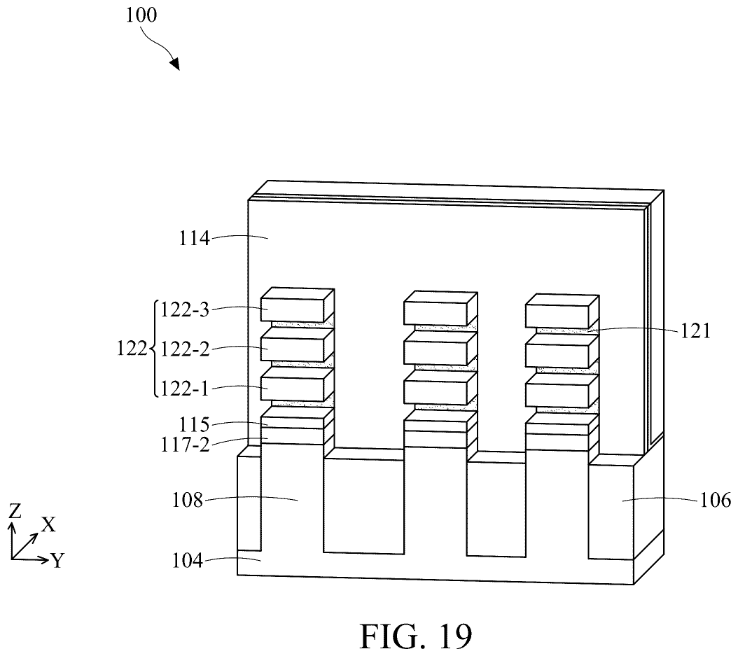

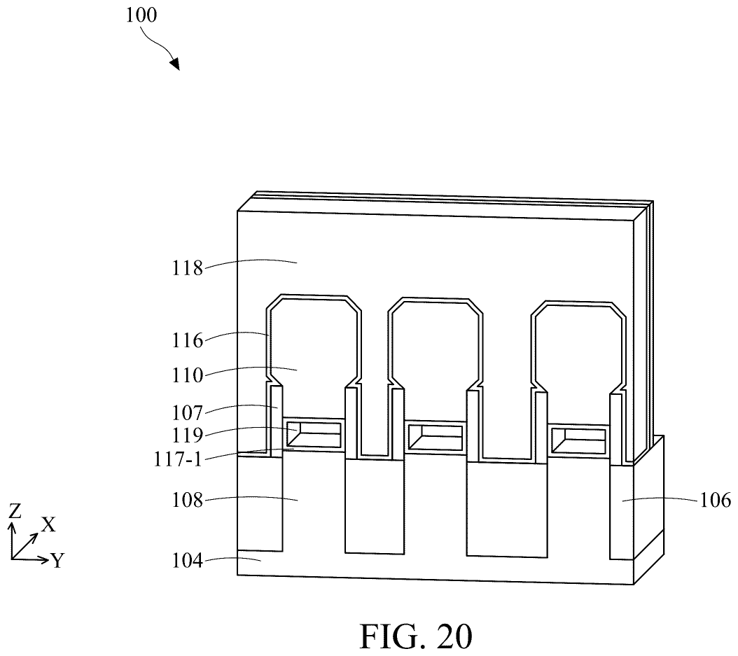

Referring to FIG. 5, in operation 560, an isolation layer is formed in the opening. For example, as shown in FIGS. 18-20, bottom isolation layer 117 can be formed in opening 1617. In some embodiments, the formation of bottom isolation layer 117 can include deposition of a layer of dielectric material 1817 in opening 1617 and removal of dielectric material 1817 deposited on nanostructures 122 outside of opening 1617. As shown in FIG. 19, dielectric material 1817 can be deposited on STI regions 106, fin structures 108, and gate spacers 114 to surround nanostructures 122 and dummy semiconductor layer 115. Dielectric material 1817 can fill second portion 1617-2 of opening 1617 to form second portion 117-2 of bottom isolation layer 117. Dielectric material 1817 can also be deposited in first portion 1617-1 under S/D structures 110 through second portion 1617-2 of opening 1617. In some embodiments, as the thickness of sacrificial semiconductor layer 717 is less than the thickness of nanostructures 721, a gap of second portion 1617-2 of opening 1617 can be less than a gap between nanostructures 122. As a result, as shown in FIGS. 18 and 19, dielectric material 1817 can fill second portion 1617-2 of opening 1617 before filling the gap between nanostructures 122. However, dielectric material 1817 may not fill first portion 1617-1 of opening 1617. First portion 117-1 of bottom isolation layer 117 can be formed along sidewall surfaces of first portion 1617-1 of opening 1617. Void 119 can be formed under S/D structures 110 and can be enclosed by first portion 117-1 of bottom isolation layer 117, as shown in FIG. 20.

In some embodiments, dielectric material 1817 can include silicon oxide, silicon nitride, silicon oxynitride, silicon carbonitride, silicon oxycarbide, silicon oxycarbonitride, hafnium oxide, aluminum oxide, or other suitable dielectric materials. In some embodiments, dielectric material 1817 can be deposited by atomic layer deposition (ALD) or other suitable deposition methods. In some embodiments, the ALD deposition process can be performed at a temperature from about 150° C. to about 300° C. under a pressure from about 0.01 Torr to about 10 Torr. In some embodiments, bottom isolation layer 117 can be a bi-layer or multi-layer structure.

In some embodiments, after second portion 1617-2 of opening 1617 is filled, dielectric material 1817 deposited on nanostructures 122 and gate spacers 114 can be removed by an etching process, as shown in FIGS. 19 and 20. As second portion 1617-2 of opening 1617 is filled with dielectric material 1817, first portion 117-1 of bottom isolation layer 117 may not be removed during the etching process due to the loading effect of the etching process. Additionally, blocked by first portion 117-1 of bottom isolation layer 117, the etching process may not remove dielectric material 1817 deposited in first portion 1617-1 of opening 1617. Accordingly, dielectric material 1817 on nanostructures 122 and gate spacers 114 can be removed during the etching process while bottom isolation layer 117 may not be removed. In some embodiments, the etching process can include a chemical dry etching process. In some embodiments, the chemical dry etching process can be performed at a temperature from about 10° C. to about 250° C. for an etching time from about 3 s to about 300 s. In some embodiments, the etchants of the chemical dry etching process can include hydrogen fluoride (HF), ammonia (NH₃), trimethylamine (N(CH₃)₃), dimethylamine (NH(CH₃)₂), methylamine (NH₂CH₃), and/or pyridine. In some embodiments, dummy semiconductor layer 115 can be removed partially or completely during the etching process. As a result, dummy semiconductor layer 115 can be optional in semiconductor device 100.

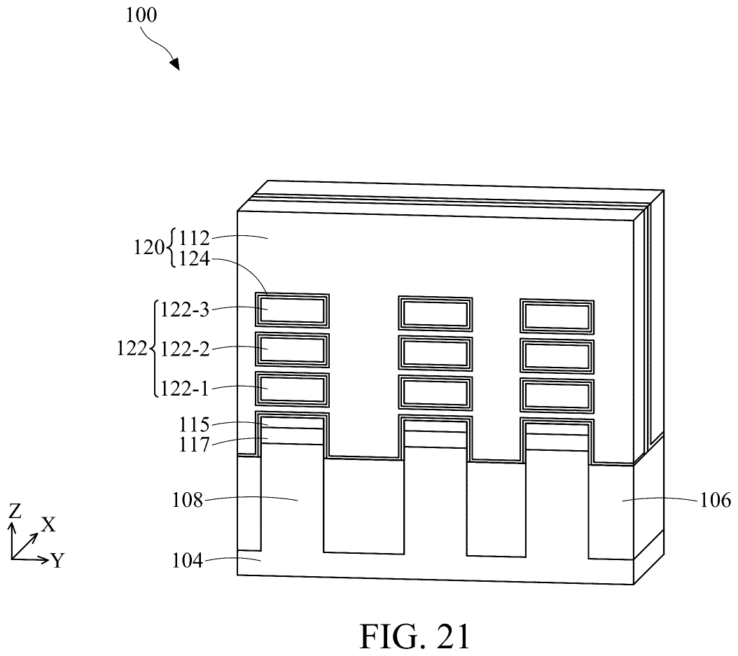

The formation of bottom isolation layer 117 can be followed by the formation of gate dielectric layer 124 and gate electrode 112, as shown in FIG. 21. In some embodiments, as void 119 is enclosed by bottom dielectric isolation layer 117, gate dielectric layer 124 and gate electrode 112 may not be deposited in void 119. In some embodiments, with bottom isolation layer 117 having void 119 between S/D structures 110 and fin structures 108/substrate 104, the leakage current between S/D structures 110 and fin structures 108/substrate 104 can be reduced. Additionally, as S/D structures 110 are epitaxially grown on sacrificial epitaxial structure 1210, the dislocation defects in S/D structures 110 can be minimized. Accordingly, bottom isolation layer 117 with void 119 can reduce the leakage current and improve the device performance.

Various embodiments in the present disclosure provide methods for forming a S/D bottom isolation layer with voids in semiconductor device 100. In some embodiments, semiconductor device 100 can include a stack of nanostructures 122 on substrate 104. Gate structures 120 can wrap around the stack of nanostructures 122. S/D structures 110 can be disposed on substrate 104 and in contact with the stack of nanostructures 122. Bottom isolation layer 117 can be disposed between S/D structures 110 and substrate 104. Bottom isolation layer 117 can enclose void 109 between S/D structures 110 and substrate 104. In some embodiments, bottom isolation layer 117 can extend below the stack of nanostructures 122. In some embodiments, semiconductor device 100 can optionally include dummy semiconductor layer 115 between gate structures 120 and bottom isolation layer 117. With bottom isolation layer 117 having void 119 between S/D structures 110 and substrate 104, the leakage current path from S/D structures 110 to substrate 104 can be blocked and the dislocation defects in S/D structures 110 can be reduced. Accordingly, bottom isolation layer 117 with void 119 can reduce the leakage current and improve the device performance. In some embodiments, the device performance can be improved by about 5% to about 10%.

In some embodiments, a semiconductor device includes a stack of semiconductor layers on a substrate, a gate structure surrounding the stack of semiconductor layers, a source/drain (S/D) structure on the substrate and adjacent to the gate structure, and an isolation layer between the S/D structure and the substrate. The isolation layer encloses a void below the S/D structure.

In some embodiments, a semiconductor device includes a stack of semiconductor layers on a substrate, a gate structure surrounding the stack of semiconductor layers, first and second source/drain (S/D) structures on opposite sides of the gate structure, and an isolation layer below the stack of semiconductor layers and the first and second S/D structures. The first and second S/D structures are in contact with the stack of semiconductor layers. The isolation layer includes a first void below the first S/D structure and a second void below the second S/D structure.

In some embodiments, a method includes depositing a sacrificial semiconductor layer, a dummy semiconductor layer, and a stack of semiconductor layers on a substrate, forming a recess adjacent to end portions of the sacrificial semiconductor layer, the dummy semiconductor layer, and the stack of semiconductor layers, forming a sacrificial epitaxial structure in the recess, forming an epitaxial structure on the sacrificial epitaxial structure, removing the sacrificial semiconductor layer and the sacrificial epitaxial structure to form an opening under the dummy semiconductor layer and the epitaxial structure, and forming an isolation layer in the opening. The isolation layer extends below the dummy semiconductor layer and encloses a void under the epitaxial structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a stack of semiconductor layers on a substrate;
a gate structure surrounding the stack of semiconductor layers;
a source/drain (S/D) structure on the substrate and in contact with the stack of semiconductor layers; and
an isolation layer between the S/D structure and the substrate, wherein the isolation layer encloses a void below the S/D structure.

2. The semiconductor device of claim 1, wherein the isolation layer extends below the stack of semiconductor layers.

3. The semiconductor device of claim 1, further comprising a dummy semiconductor layer between the gate structure and the isolation layer, wherein the dummy semiconductor layer is in contact with the isolation layer.

4. The semiconductor device of claim 3, wherein a thickness of the dummy semiconductor layer ranges is less than about 10 nm.

5. The semiconductor device of claim 3, further comprises a shallow trench isolation (STI) region surrounding the stack of semiconductor layers, wherein a distance between a top surface of the STI region and a bottom surface of the dummy semiconductor layer ranges from about 5 nm to about 20 nm.

6. The semiconductor device of claim 1, wherein a thickness of the isolation layer below the S/D structure ranges from about 0.5 nm to about 4 nm.

7. The semiconductor device of claim 1, wherein a thickness of the isolation layer below the stack of semiconductor layers ranges from about 1 nm to about 10 nm.

8. The semiconductor device of claim 1, wherein the isolation layer comprises at least one of silicon oxide, silicon nitride, silicon carbonitride, silicon oxycarbide, silicon oxycarbonitride, hafnium oxide, and aluminum oxide.

9. The semiconductor device of claim 1, further comprising an additional S/D structure on the substrate, wherein:
the S/D structure and the additional S/D structure are on opposite sides of the gate structure,
the isolation layer extends below the additional S/D structure, and
the isolation layer comprises an additional void below the additional S/D structure.

10. A semiconductor device, comprising:
a stack of semiconductor layers on a substrate;
a gate structure surrounding the stack of semiconductor layers;
first and second source/drain (S/D) structures on opposite sides of the gate structure, wherein the first and second S/D structures are in contact with the stack of semiconductor layers; and
an isolation layer below the stack of semiconductor layers and the first and second S/D structures, wherein the isolation layer comprises a first void below the first S/D structure and a second void below the second S/D structure.

11. The semiconductor device of claim 10, further comprising a dummy semiconductor layer between the gate structure and the isolation layer, wherein the dummy semiconductor layer is in contact with the isolation layer.

12. The semiconductor device of claim 11, wherein the dummy semiconductor layer is disposed below the stack of semiconductor layers and between the first and second voids.

13. The semiconductor device of claim 11, wherein a thickness of the dummy semiconductor layer is less than about 10 nm.

14. The semiconductor device of claim 11, further comprises a shallow trench isolation (STI) region surrounding the stack of semiconductor layers, wherein a top surface of the STI region is below a bottom surface of the dummy semiconductor layer.

15. The semiconductor device of claim 10, wherein a thickness of the isolation layer enclosing the first and second voids ranges from about 0.5 nm to about 4 nm.

16. The semiconductor device of claim 10, wherein a thickness of the isolation layer between the first and second voids ranges from about 1 nm to about 10 nm.

17. A method, comprising:
depositing a sacrificial semiconductor layer, a dummy semiconductor layer, and a stack of semiconductor layers on a substrate;
forming a recess adjacent to end portions of the sacrificial semiconductor layer, the dummy semiconductor layer, and the stack of semiconductor layers;
forming a sacrificial epitaxial structure in the recess;
forming an epitaxial structure on the sacrificial epitaxial structure;
removing the sacrificial semiconductor layer and the sacrificial epitaxial structure to form an opening under the dummy semiconductor layer and the epitaxial structure; and
forming an isolation layer in the opening, wherein the isolation layer extends below the dummy semiconductor layer and encloses a void under the epitaxial structure.

18. The method of claim 17, wherein forming the isolation layer comprises:
depositing a layer of dielectric material surrounding the dummy semiconductor layer and the stack of semiconductor layers; and
removing the layer of dielectric material surrounding the stack of semiconductor layers.

19. The method of claim 17, further comprising forming a gate structure surrounding the stack of semiconductor layers and the dummy semiconductor layer.

20. The method of claim 17, wherein forming the sacrificial epitaxial structure comprises epitaxially growing a silicon germanium layer, and wherein germanium concentrations of the sacrificial semiconductor layer and the sacrificial epitaxial structure are greater than that of the stack of semiconductor layers.
